(19) United States
(12) Patent Application Publication
(10) Pub. No.: US 2009/0102015 A1
(43) Pub. Date: Apr. 23, 2009

(54) Integrated Circuit, Memory Cell Array, Memory Cell, Memory Module, Method of Operating an Integrated Circuit, and Method of Manufacturing an Integrated Circuit

(76) Inventors: Ulrich Klostermann, Munich (DE); Dietmar Gogl, Essex Junction, VT (US)

Correspondence Address: SLATER & MATSIL, L.L.P., 17950 PRESTON ROAD, SUITE 1000, DALLAS, TX, 75252, US

(21) Appl. No.: 11/874,113

(22) Filed: Oct. 17, 2007

(51) Int. Cl. H01L 29/92; H01L 21/77

(52) U.S. Cl. 257/532; 438/393; 257/E21.008; 257/E29.001

(57) ABSTRACT

According to one embodiment of the present invention, an integrated circuit includes a plurality of resistivity changing memory cells, each memory cell including a top electrode, a bottom electrode and resistivity changing material being disposed between the top electrode and the bottom electrode. The top electrodes together form a continuous common first electrode. Alternatively, a first continuous common electrode which is electrically connected to all top electrodes is disposed above the top electrodes. A second electrode connectable to a fixed potential is disposed above the first electrode such that the first electrode and the second electrode together form a capacitor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of an integrated circuit;

FIG. 1B shows an equivalent circuit of a part of the integrated circuit shown in FIG. 1A;

FIG. 2A shows a cross-sectional view of an integrated circuit according to one embodiment of the present invention;

FIG. 2B shows an equivalent circuit of a part of the integrated circuit shown in FIG. 2A;

FIG. 3 shows a top view of an integrated circuit according to one embodiment of the present invention;

FIG. 4 shows a top view of an integrated circuit according to one embodiment of the present invention;

FIG. 5 shows a cross-sectional view of an integrated circuit according to one embodiment of the present invention;

FIG. 6 shows a flow-chart of a method of operating an integrated circuit according to one embodiment of the present invention;

FIG. 7A shows a cross-sectional view of a solid electrolyte memory device set to a first switching state;

FIG. 7B shows a cross-sectional view of a solid electrolyte memory device set to a second switching state;

FIG. 8 shows a cross-sectional view of a phase changing memory device;

FIG. 9 shows a schematic drawing of an integrated circuit according to one embodiment of the present invention;

FIG. 10A shows a cross-sectional view of a carbon memory device set to a first switching state;

FIG. 10B shows a cross-sectional view of a carbon memory device set to a second switching state;

FIG. 11A shows an integrated circuit according to one embodiment of the present invention;

FIG. 11B shows an integrated circuit according to one embodiment of the present invention;

FIG. 12A shows a memory module according to one embodiment of the present invention; and

FIG. 12B shows a memory module according to one embodiment of the present invention.

### DETAILED DESCRIPTION OF ILLUSTRATIVE EMBODIMENTS

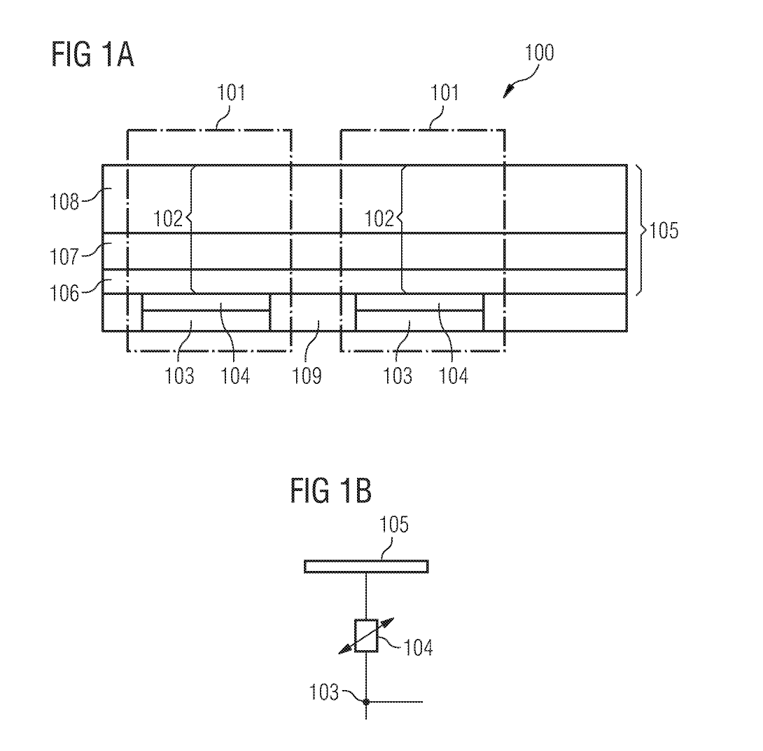

FIG. 1A shows a cross-sectional view of an integrated circuit 100, FIG. 1B the equivalent circuit thereof. Here, it is assumed that the integrated circuit 100 is a solid electrolyte memory device. The integrated circuit 100 includes a plurality of resistivity changing memory cells 101, each memory cell 101 including a top electrode 102, a bottom electrode 103, and resistivity changing material 104 being disposed between the top electrode 102 and the bottom electrode 103. The top electrodes 102 together form a continuous common first electrode 105. According to one embodiment of the present invention, the term “continuous common first electrode” means an electrode which is common in an electrical sense, i.e., the electrode may be patterned, the patterned parts however being electrically connected with each other. Alternatively, according to one embodiment of the present invention, this term means a mechanically continuous electrode, i.e., an unpatterned electrode. Here, the first electrode 105 includes a first conductive layer 106 which may, for example, include or consist of silver, a second conductive layer 107 (cap layer) which may, for example, include or consist of tantalum or tantalum nitride, and a third conductive layer 108 which may, for example, include or consist of tantalum, tantalum nitride, or titanium nitride. The bottom electrodes 103 and the resistivity changing material blocks 104 are isolated against each other by an isolation layer 109.

The memory states of the memory cells 101 can be programmed and sensed by applying a voltage between the top electrodes 102 and the bottom electrodes 103. The voltage applied between the top electrodes 102 and the bottom electrodes 103 has to be kept as constant as possible. As a consequence, the potential of the first electrode 105 has to be kept as constant as possible. Usually, the potential of the first electrode 105 is generated by a circuitry. The potential generated by the circuitry usually shows potential fluctuations. As a consequence, also the potential at the first electrode 105 may be subjected to potential fluctuations. However, potential fluctuations at the first electrode 105 may lead to errors during memory state writing processes or memory state sensing processes.

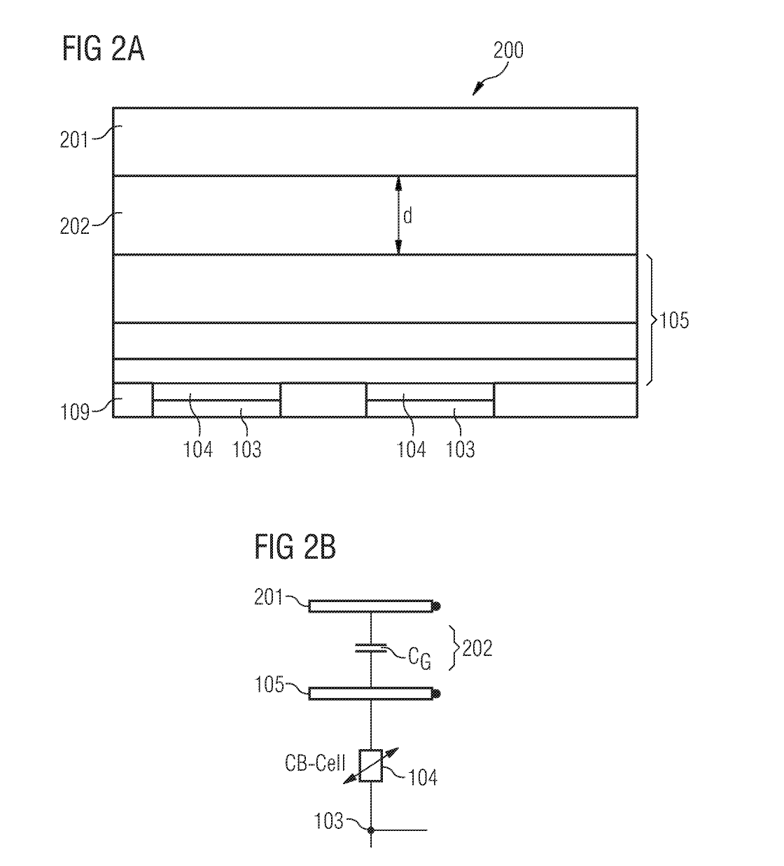

FIG. 2A shows a cross-sectional view of an integrated circuit 200 according to one embodiment of the present invention having the same architecture as the integrated circuit 100 shown in FIG. 1A. Additionally, a second electrode 201 (guard electrode) being set (or being connectable (e.g., via a switch)) to a fixed potential is disposed above the first electrode 105. Between the first electrode 105 and the second electrode 201, isolation material 202 is disposed.

According to one embodiment of the present invention, the fixed potential of the second electrode 201 is chosen such that potential fluctuations of the potential of the first electrode 105 are decreased during the operation of the integrated circuit 200.

According to one embodiment of the present invention, the isolation material 202 includes or consists of SiO₂ (silicon oxide), SiN (silicon nitride), Al₂O₃ (aluminum oxide), AlN (aluminum nitride), ZrOₓ (zirconium oxide), HfOₓ (hafnium oxide), or GeS (germanium sulfide).

According to one embodiment of the present invention, the material of the upper part of the first electrode 105 (which corresponds to the third conductive layer 108 in FIG. 1A) and the second electrode 201 includes or consists of Cu (copper), Ru (Ruthenium), W (tungsten), Ta (tantalum), TaN (tantalum nitride), or TiN (titanium nitride).

According to one embodiment of the present invention, the distance d between the first electrode 105 and the second electrode 201 is about 10 nm.

FIG. 2B shows the equivalent circuit of the integrated circuit 200 shown in FIG. 2A. As can be derived from FIG. 2B, the first electrode 105, the isolation material 202 and the second electrode 201 together form a capacitor which capacitively couples the first electrode 105 to the second electrode 201, the second electrode 201 being set to a fixed potential. One effect of the capacitive coupling between the first electrode 105 and the second electrode 201 is that potential fluctuations of a potential which is supplied to the first electrode 105 (and which may, for example, be generated by a circuitry) are at least partly compensated, thereby lowering the potential fluctuations within the first electrode 105. In this way, the precision of memory cell programming processes or memory cell reading processes can be increased.

According to one embodiment of the present invention, the dielectric constant ∈ᵣ of the isolation material 202 lies within a range extending from about 3.9 to about 9.

According to one embodiment of the present invention, the dielectric constant ∈ᵣ of the isolation material 202 is about 25.

According to one embodiment of the present invention, the capacity of the capacitor formed by the first electrode 105, the isolation material 202 and the second electrode 201 is about 20 pF. Generally, the capacity and the value of the fixed potential of the second electrode 201 are chosen such that “normal” potential fluctuations occurring within the first electrode 105 can be stabilized.

According to one embodiment of the present invention, the resistivity changing material is, for example, solid electrolyte material, phase changing material, transition metal oxide material, or magneto-resistive material. The present invention is not restricted to these materials.

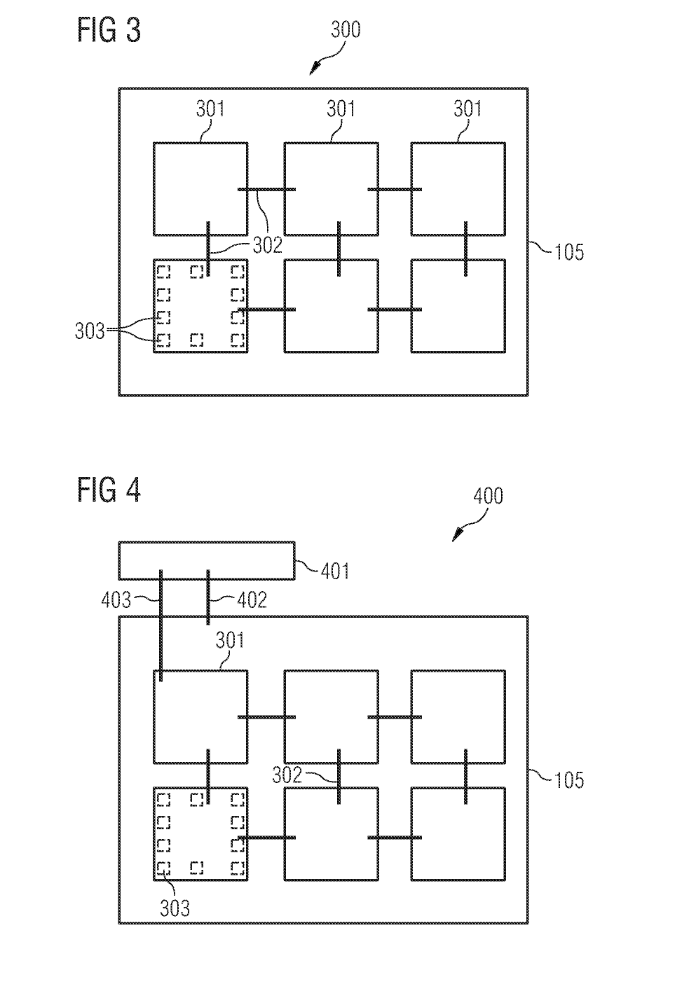

FIG. 3 shows a top view of an integrated circuit 300 (for example, a top view of the integrated circuit 200) according to one embodiment of the present invention. Here, the second electrode 201 has been patterned into several electrode sub-units 301, wherein each electrode sub-unit 301 faces a plurality of top electrodes 102. That is, each electrode sub-unit 301 covers a plurality of top electrodes 102. Here, the electrode sub-units 301 are electrically connected with each other by at least electrical connections 302. One effect of the electrical connections 302 is that the potential of the different electrode sub-units 301 is widely uniform which ensures increased reproducibility during the memory state reading processes or memory state programming processes. However, the electric connections 302 may also be omitted.

According to one embodiment of the present invention, at least portions of electrode sub-units 301 are perforated and/or striped.

According to one embodiment of the present invention, each electrode sub-unit 301 (or at least one electrode sub-unit 301) is electrically connected to a substrate of the integrated circuit 300 by means of vias 303 which are indicated in FIG. 3 by dotted lines. The vias 303 may, for example, be located at or near the borders of the electrode sub-units 301 or also at other positions.

According to one embodiment of the present invention, the dimensions and positions of the electrode sub-unit 301 are chosen such that delamination effects of the patterned second electrode 201 are reduced as much as possible (it is less likely that a plurality of electrode sub-units 301 delaminate than one single large second electrode 201).

FIG. 4 shows an integrated circuit 400 having the same architecture as the integrated circuit 300 shown in FIG. 3. In addition, a controlling circuit or peripheral circuit 401 is connected to the first electrode 105 by an electric connection 402. The controlling circuit or peripheral circuit 401 is further connected to the electrode sub-units 301 by an electric connection 403. The potential of the first electrode 105 is supplied to the controlling circuit/peripheral circuit 401 via the electric connection 402. The potential of the electrode sub-units 301 is supplied to the controlling circuit/peripheral circuit 401 via the electric connection 403. The integrated circuit 400 may be arranged such that these potentials can be used by the controlling circuit/peripheral circuit 401 as follows: the electrode sub-units 301 (guard plates) can be set to a fixed potential being different from the fixed potential to which the first electrode 105 is set, e.g., to zero potential by using vias to a ground contact as described before. The peripheral circuit 401 can monitor these potentials via the electric connections 402 and 403. In this way, during a reading process, a signal margin can be enhanced if potential fluctuations, which will occur at both the first electrode 105 and the electrode sub-units 301, will subtractively be taken into account, thus cancelling out the potential fluctuations; the same holds true for a writing processes.

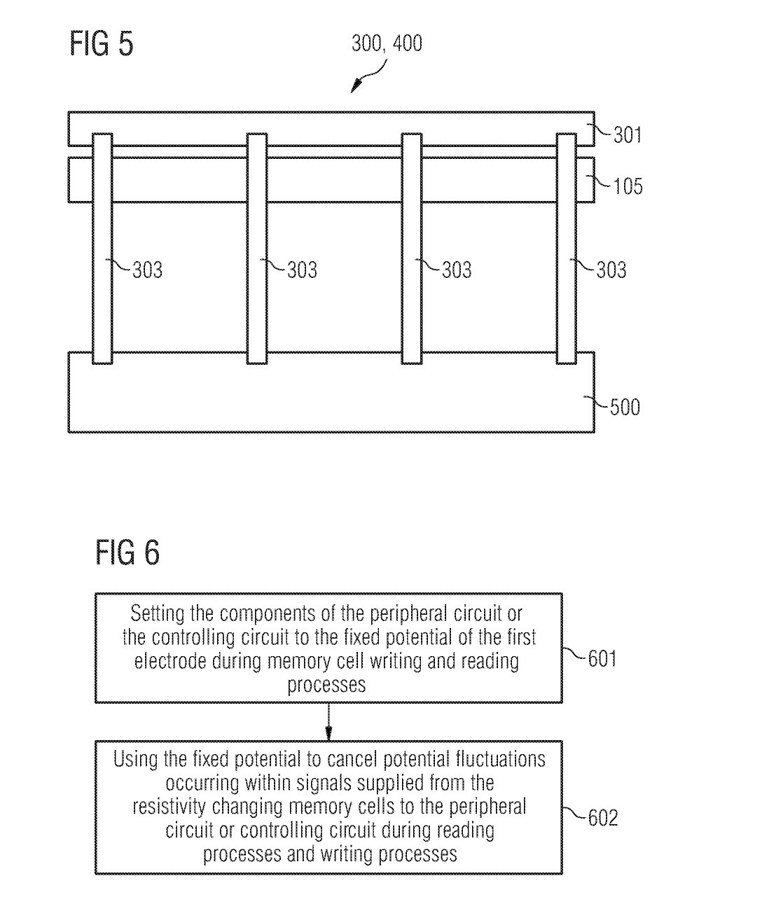

FIG. 5 shows a cross-sectional view of a part of the integrated circuit 300 and 400 shown in FIGS. 3 and 4. In FIG. 5, an electrode sub-unit 301 is shown which is connected to a substrate 500 (for example, a semiconductor substrate or ground mesh potential) of the integrated circuit 300 or 400 by means of conductive vias 303. The conductive vias 303 extend through the first electrode 105 (not shown here) and are isolated against their environment by isolation material. The ground mesh potential can be buried into the substrate (using, e.g., doped silicon wires or plates) or consist of metallization levels above the selection device.

In the foregoing description, the memory cells 101 of the integrated circuits have been assumed to be solid electrolyte memory cells (programmable metallization memory cells). However, the invention is not restricted thereto. Arbitrary resistivity changing memory cells may be used, for example, phase changing memory cells, carbon memory cells, magneto-resistive memory cells, organic memory cells, or transition metal oxide memory cells.

According to one embodiment of the present invention, a memory cell array including a plurality of resistivity changing memory cells is provided. Each memory cell includes a top electrode, a bottom electrode, and resistivity changing material being disposed between the top electrode and the bottom electrode. The top electrodes together form a continuous common first electrode. Alternatively, a first continuous common electrode which is electrically connected to all top electrodes is disposed above the top electrodes. A second electrode being set (or being connectable (e.g., via a switch)) to a fixed potential is disposed above the first electrode such that the first electrode and the second electrode together form a capacitor.

According to one embodiment of the present invention, the memory cell array may be split into a plurality of memory cell array subunits. Further, the second electrode is patterned into several electrode subunits, each electrode subunit facing a plurality of top electrodes. For example, each memory cell array subunit may at least partially be covered by one of the electrode subunits. For example, referring to FIG. 3, all memory cells covered by one electrode subunit 301 may constitute a memory cell array subunit, wherein all memory cell subunits together form the integrated circuit 300 (or at least a part thereof).

According to one embodiment of the present invention, a memory cell including a top electrode layer, a bottom electrode layer and a resistivity changing layer being disposed between the top electrode layer and the bottom electrode layer is provided. A further electrode layer being set (or being connectable (e.g., via a switch)) to a fixed potential is disposed above the top electrode layer such that the top electrode layer and the further electrode layer together form a capacitor.

According to one embodiment of the present invention, the subunits of the top electrode (guard electrode) consist of multiple metallization lines which are connected together by at least one contact to a common potential.

According to one embodiment of the present invention, at least portions of the guard electrode (second electrode) is fine-patterned in order to ensure a better stress relaxation, thus reducing the risk of delamination.

According to one embodiment of the present invention, the fine-patterning of the guard electrode (second electrode) may be carried out using a perforation of the guard electrode.

According to one embodiment of the present invention, the fine-patterning results in a guard electrode having lines and stripes.

All embodiments discussed in conjunction with the embodiments of the integrated circuit can also be applied to the memory cell array and the memory cell, as far as applicable.

The present invention further provides a memory module including at least one integrated circuit including a plurality of resistivity changing memory cells, each memory cell including a top electrode, a bottom electrode and resistivity changing material being disposed between the top electrode and the bottom electrode. The top electrodes together form a continuous common first electrode. Alternatively, a first continuous common electrode which is electrically connected to all top electrodes is disposed above the top electrodes. A second electrode being set (or being connectable (e.g., via a switch)) to a fixed potential is disposed above the first electrode such that the first electrode and the second electrode together form a capacitor.

According to one embodiment of the present invention, the memory module is stackable.

FIG. 6 shows a method of operating an integrated circuit according to one embodiment of the present invention. The integrated circuit includes a plurality of resistivity changing memory cells, each memory cell including a top electrode, a bottom electrode and resistivity changing material being disposed between the top electrode and the bottom electrode. The top electrodes together form a continuous common first electrode. Alternatively, a first continuous common electrode which is connected to all top electrodes is disposed above the top electrodes. A second electrode being set to a fixed potential is disposed above the first electrode such that the first electrode and the second electrode together form a capacitor. The integrated circuit further includes a peripheral circuit or controlling circuit which include components (at least one component) set to a fixed potential.

At 601, the components of the peripheral circuit or the controlling circuit are set to the potential of the first electrode during memory cell writing processes and memory cell reading processes. At 602, the fixed potentials are used to cancel potential fluctuations occurring within signals supplied from the resistivity changing memory cells to the peripheral circuit or controlling circuit or controlling circuit during reading processes and writing processes. In this way, the precision of the reading processes and writing processes can be increased.

According to one embodiment of the present invention, the integrated circuit 400 as shown in FIG. 4 may, for example, be used in order to carry out the method 600.

According to one embodiment of the present invention, a method of manufacturing an integrated circuit is provided, comprising: providing a plurality of resistivity changing memory cells, each memory cell comprising a top electrode, a bottom electrode, and a resistivity changing region being disposed between the top electrode and the bottom electrode, wherein the top electrodes together form a continuous common first electrode layer, or wherein a first continuous common electrode layer is disposed above the top electrodes which is connected to all top electrodes; providing an isolation layer on the first electrode layer; and providing a second electrode layer on the isolation layer.

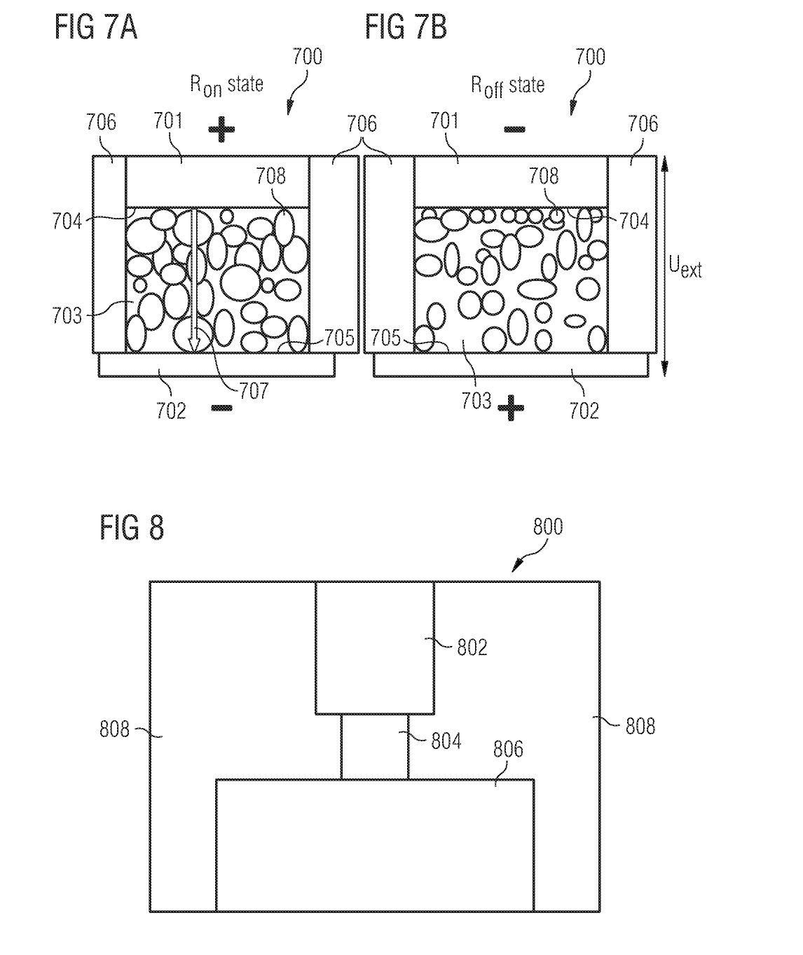

Since the embodiments of the present invention can be applied to programmable metallization cell devices (PMC) (e.g., solid electrolyte devices like CBRAM (conductive bridging random access memory) devices), in the following description, making reference to FIGS. 7A and 7B, a basic principle underlying embodiments of CBRAM devices will be explained.

As shown in FIG. 7A, a CBRAM cell 700 includes a first electrode 701 a second electrode 702, and a solid electrolyte block (in the following also referred to as ion conductor block) 703 which includes the active material and which is sandwiched between the first electrode 701 and the second electrode 702. This solid electrolyte block 703 can also be shared between a plurality of memory cells (not shown here). The first electrode 701 contacts a first surface 704 of the ion conductor block 703, the second electrode 702 contacts a second surface 705 of the ion conductor block 703. The ion conductor block 703 is isolated against its environment by an isolation structure 706. The first surface 704 usually is the top surface, the second surface 705 the bottom surface of the ion conductor 703. In the same way, the first electrode 701 generally is the top electrode, and the second electrode 702 the bottom electrode of the CBRAM cell. One of the first electrode 701 and the second electrode 702 is a reactive electrode, the other one an inert electrode. Here, the first electrode 701 is the reactive electrode, and the second electrode 702 is the inert electrode. In this example, the first electrode 701 includes silver (Ag), the ion conductor block 703 includes silver-doped chalcogenide material, the second electrode 702 includes tungsten (W), and the isolation structure 706 includes SiO₂ or Si₃N₄. An embodiment of the present invention is however not restricted to these materials. For example, the first electrode 701 may alternatively or additionally include copper (Cu) or zinc (Zn), and the ion conductor block 703 may alternatively or additionally include copper-doped chalcogenide material. Further, the second electrode 702 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 703 may, for example, range between about 5 nm and about 500 nm. The thickness of the first electrode 701 may, for example, range between about 10 nm and about 100 nm. The thickness of the second electrode 702 may, for example, range between about 5 nm and about 500 nm, between about 15 nm to about 150 nm, or between about 25 nm and about 100 nm. It is to be understood that an embodiment of the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 7A is applied across the ion conductor block 703, a redox reaction is initiated which drives Ag⁺ ions out of the first electrode 701 into the ion conductor block 703 where they are reduced to Ag, thereby forming Ag rich clusters 708 within the ion conductor block 703. If the voltage applied across the ion conductor block 703 is applied for an enhanced period of time, the size and the number of Ag rich clusters within the ion conductor block 703 is increased to such an extent that a conductive bridge 707 between the first electrode 701 and the second electrode 702 is formed. In case that a voltage is applied across the ion conductor 703 as shown in FIG. 7B (inverse voltage compared to the voltage applied in FIG. 7A), a redox reaction is initiated which drives Ag⁺ ions out of the ion conductor block 703 into the first electrode 701 where they are reduced to Ag. As a consequence, the size and the number of Ag rich clusters within the ion conductor block 703 is reduced, thereby erasing the conductive bridge 707. After having applied the voltage/inverse voltage, the memory cell 700 remains within the corresponding defined switching state even if the voltage/inverse voltage has been removed.

In order to determine the current memory status of a CBRAM cell, for example, a sensing current is routed through the CBRAM cell. The sensing current experiences a high resistance in case no conductive bridge 707 exists within the CBRAM cell, and experiences a low resistance in case a conductive bridge 707 exists within the CBRAM cell. A high resistance may, for example, represent “0”, whereas a low resistance represents “1”, or vice versa. The memory status detection may also be carried out using sensing voltages. Alternatively, a sensing voltage may be used in order to determine the current memory status of a CBRAM cell.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For the sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistivity of the resistivity changing memory cell, which represents the memory state of the memory cell.

FIG. 8 illustrates a cross-sectional view of an exemplary phase changing memory cell 800 (active-in-via type). The phase changing memory cell 800 includes a first electrode 802, a phase changing material 804, a second electrode 806, and an insulating material 808. The phase changing material 804 is laterally enclosed by the insulating material 808. To use the phase changing memory cell, a selection device (not shown), such as a transistor, a diode, or another active device, may be coupled to the first electrode 802 or to the second electrode 806 to control the application of a current or a voltage to the phase changing material 804 via the first electrode 802 and/or the second electrode 806. To set the phase changing material 804 to the crystalline state, a current pulse and/or voltage pulse may be applied to the phase changing material 804, wherein the pulse parameters are chosen such that the phase changing material 804 is heated above its crystallization temperature, while keeping the temperature below the melting temperature of the phase changing material 804. To set the phase changing material 804 to the amorphous state, a current pulse and/or voltage pulse may be applied to the phase changing material 804, wherein the pulse parameters are chosen such that the phase changing material 804 is quickly heated above its melting temperature, and is quickly cooled.

The phase changing material 804 may include a variety of materials. According to one embodiment, the phase changing material 804 may include or consist of a chalcogenide alloy that includes one or more elements from group VI of the periodic table. According to another embodiment, the phase changing material 804 may include or consist of a chalcogenide compound material, such as GeSbTe, SbTe, GeTe or AgInSbTe. According to a further embodiment, the phase changing material 804 may include or consist of chalcogen free material, such as GeSb, GaSb, InSb, or GeGaInSb. According to still another embodiment, the phase changing material 804 may include or consist of any suitable material including one or more of the elements Ge, Sb, Te, Ga, Bi, Pb, Sn, Si, P, O, As, In, Se, and S.

According to one embodiment, at least one of the first electrode 802 and the second electrode 806 may include or consist of Ti, V, Cr, Zr, Nb, Mo, Hf, Ta, W, or mixtures or alloys thereof. According to another embodiment, at least one of the first electrode 802 and the second electrode 806 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TIAlN, TiSiN, W—Al₂O₃ and Cr—Al₂O₃.

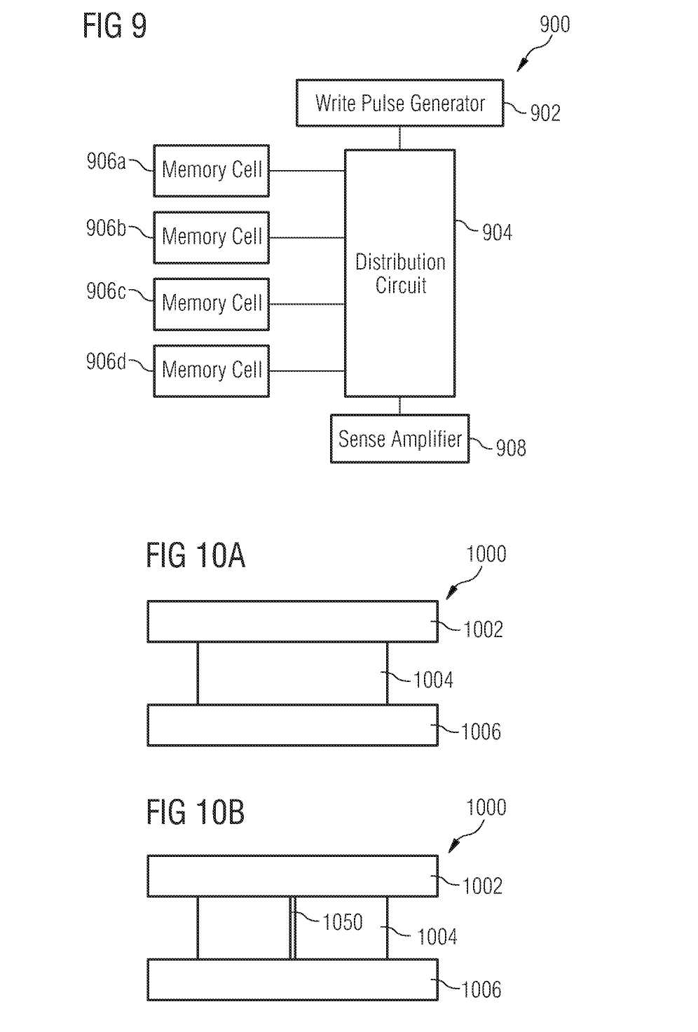

FIG. 9 illustrates a block diagram of a memory device 900 including a write pulse generator 902, a distribution circuit 904, phase changing memory cells 906a, 906b, 906c, 906d (for example phase changing memory cell 800 as shown in FIG. 8), and a sense amplifier 908. According to one embodiment, the write pulse generator 902 generates current pulses or voltage pulses that are supplied to the phase changing memory cells 906a, 906b, 906c, 906d via the distribution circuit 904, thereby programming the memory states of the phase changing memory cells 906a, 906b, 906c, 906d. According to one embodiment, the distribution circuit 904 includes a plurality of transistors that supply direct current pulses or direct voltage pulses to the phase changing memory cells 906a, 906b, 906c, 906d or to heaters being disposed adjacent to the phase changing memory cells 906a, 906b, 906c, 906d.

As already indicated, the phase changing material of the phase changing memory cells 906a, 906b, 906c, 906d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 908 is capable of determining the memory state of one of the phase changing memory cells 906a, 906b, 906c, or 906d in dependence on the resistance of the phase changing material.

To achieve high memory densities, the phase changing memory cells 906a, 906b, 906c, 906d may be capable of storing multiple bits of data, i.e., the phase changing material may be programmed to more than two resistance values. For example, if a phase changing memory cell 906a, 906b, 906c, 906d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 9 may also be applied in a similar manner to other types of resistivity changing memory cells like programmable metallization cells (PMCs), magento-resistive memory cells (e.g., MRAMs), organic memory cells (e.g., ORAMs), or transition oxide memory cells (TMOs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between a sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 10A and 10B.

FIG. 10A shows a carbon memory cell 1000 that includes a top contact 1002, a carbon storage layer 1004 including an insulating amorphous carbon material rich in sp³-hybridized carbon atoms, and a bottom contact 1006. As shown in FIG. 10B, by forcing a current (or voltage) through the carbon storage layer 1004, a sp² filament 1050 can be formed in the sp³-rich carbon storage layer 1004, changing the resistivity of the memory cell. Application of a current (or voltage) pulse with higher energy (or, in some embodiments, reversed polarity) may destroy the sp² filament 1050, increasing the resistance of the carbon storage layer 1004. As discussed above, these changes in the resistance of the carbon storage layer 1004 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

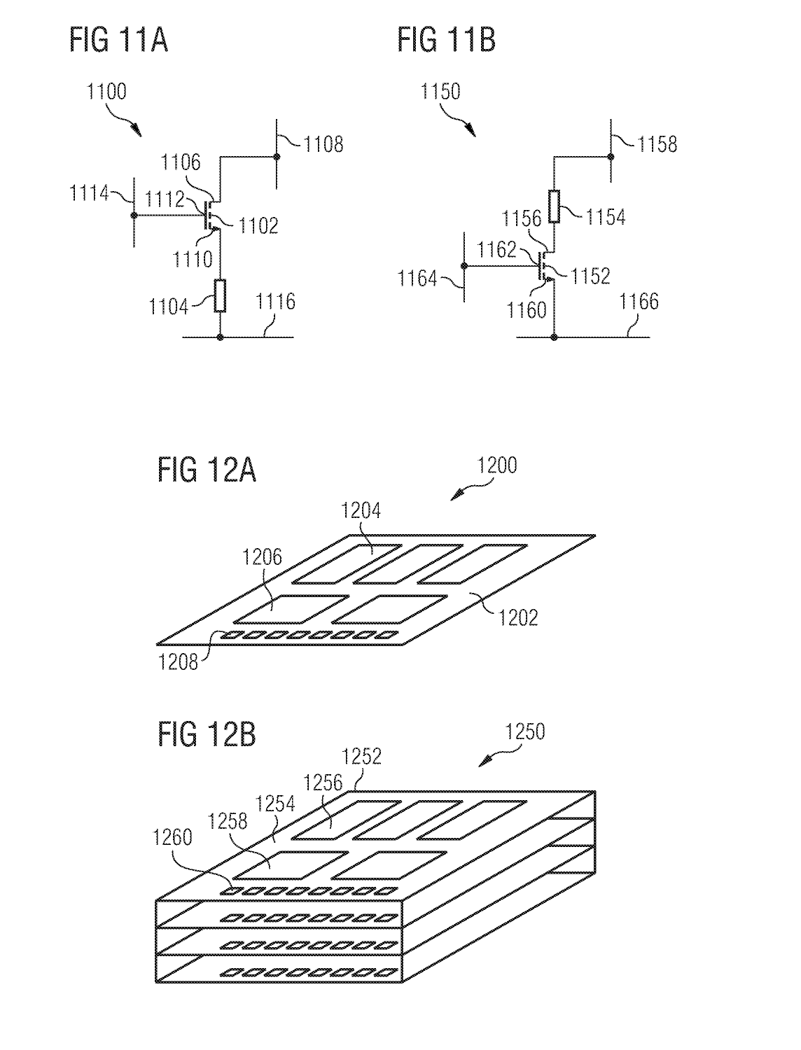

Resistivity changing memory cells, such as the phase changing memory cells and carbon memory cells described above, may include a transistor, diode, or other active component for selecting the memory cell. FIG. 11A shows a schematic representation of such a memory cell that uses a resistivity changing memory element. The memory cell 1100 includes a select transistor 1102 and a resistivity changing memory element 1104. The select transistor 1102 includes a source 1106 that is connected to a bit line 1108, a drain 1110 that is connected to the memory element 1104, and a gate 1112 that is connected to a word line 1114. The resistivity changing memory element 1104 also is connected to a common line 1116, which may be connected to ground, or to other circuitry, such as circuitry (not shown) for determining the resistance of the memory cell 1100, for use in reading. Alternatively, in some configurations, circuitry (not shown) for determining the state of the memory cell 1100 during reading may be connected to the bit line 1108. It should be noted that as used herein the terms connected and coupled are intended to include both direct and indirect connection and coupling, respectively.

To write to the memory cell 1100, the word line 1114 is used to select the memory cell 1100, and a current (or voltage) pulse on the bit line 1108 is applied to the resistivity changing memory element 1104, changing the resistance of the resistivity changing memory element 1104. Similarly, when reading the memory cell 1100, the word line 1114 is used to select the cell 1100, and the bit line 1108 is used to apply a reading voltage (or current) across the resistivity changing memory element 1104 to measure the resistance of the resistivity changing memory element 1104.

The memory cell 1100 may be referred to as a 1T1J cell, because it uses one transistor, and one memory junction (the resistivity changing memory element 1104). Typically, a memory device will include an array of many such cells. It will be understood that other configurations for a 1T1J memory cell, or configurations other than a 1T1J configuration may be used with a resistivity changing memory element. For example, in FIG. 11B, an alternative arrangement for a 1T1J memory cell 1150 is shown, in which a select transistor 1152 and a resistivity changing memory element 1154 have been repositioned with respect to the configuration shown in FIG. 11A. In this alternative configuration, the resistivity changing memory element 1154 is connected to a bit line 1158, and to a source 1156 of the select transistor 1152. A drain 1160 of the select transistor 1152 is connected to a common line 1166, which may be connected to ground, or to other circuitry (not shown), as discussed above. A gate 1162 of the select transistor 1152 is controlled by a word line 1164.

As shown in FIGS. 12A and 12B, in some embodiments, integrated circuits such as those described herein may be used in modules. In FIG. 12A, a memory module 1200 is shown, on which one or more integrated circuits 1204 are arranged on a substrate 1202. The integrated circuits 1204 include numerous memory cells according to one embodiment of the present invention. The memory module 1200 may also include one or more electronic devices 1206, which may include memory, processing circuitry, control circuitry, addressing circuitry, bus interconnection circuitry, or other circuitry or electronic devices that may be combined on a module with a memory device, such as the integrated circuits 1204. Additionally, the memory module 1200 includes multiple electrical connections 1208, which may be used to connect the memory module 1200 to other electronic components, including other modules.

As shown in FIG. 12B, in some embodiments, these modules may be stackable, to form a stack 1250. For example, a stackable memory module 1252 may contain one or more integrated circuits 1256, arranged on a stackable substrate 1254. The integrated circuits 1256 contain memory cells in accordance with an embodiment of the invention. The stackable memory module 1252 may also include one or more electronic devices 1258, which may include memory, processing circuitry, control circuitry, addressing circuitry, bus interconnection circuitry, or other circuitry or electronic devices that may be combined on a module with a memory device, such as the integrated circuits 1256. Electrical connections 1260 are used to connect the stackable memory module 1252 with other modules in the stack 1250, or with other electronic devices. Other modules in the stack 1250 may include additional stackable memory modules, similar to the stackable memory module 1252 described above, or other types of stackable modules, such as stackable processing modules, control modules, communication modules, or other modules containing electronic components.

In the following description, further aspects of exemplary embodiments of the present invention will be explained.

According to one embodiment of the present invention, the second electrode is connected to ground potential (e.g. 0V).

According to one embodiment of the present invention, the size of an electrode subunit is A=(n_x*pitch x)*(n_y*pitch_y), wherein “pitch” is the pitch between two memory cells, and n=256 (more generally, n may range between 128 and 1024), and wherein x and y refer to orthogonal directions.

According to one embodiment of the present invention, an additional capacitively coupled guard plate parallel to the PL plate (first conductive common electrode) is used. If no additional capacitively coupled guard plate is used, possible effects are: noise fluctuations at read; reduced readout sensitivity; and reduced yield.

According to one embodiment of the present invention, a stable low noise PL plate voltage relative to peripheral circuits ground surrounding local sub arrays is provided.

According to one embodiment of the present invention, the guard plate supports ground distribution between sub arrays of the memory device.

According to one embodiment of the present invention, effects of embodiments of the present invention include reduced read times, better read signals, and yield improvement.

CBRAM memory technology is considered as a promising option for non-volatile memories. For high cell densities the PL plate concept is used. In order to enable a reliable cell read-out, the PL plate is usually biased at a high potential, which is problematic with respect to potential fluctuations. The high potential usually comes from the noisy supply voltage of the chip or will be stabilized by a regulator. These voltage sources are either noisy or have to be distributed over long distances to the sub arrays of the memory device. Switching noise or voltage drops can easily reduce read margin and yield.

A more convenient way would be to operate the PL plate at ground potential which is considered to be stable. However, this is currently not feasible due to the polarity requirements of CBRAM cells.

Thus, according to one embodiment of the present invention, in order to improve the noise fluctuation of the PL plate the PL plate is capacitively coupled to ground. The coupling is provided via a 2nd “guard” plate in parallel to the PL plate. The guard plate is connected to ground potential.

According to one embodiment of the present invention, the guard plate will be connected to the peripheral circuits ground, e.g., sense amplifier, surrounding the sub arrays. This ensures that input signals to the sense amplifier (derived from the CBRAM cell connected to the PL plate) and sense amplifier ground will stay in phase due to the buffer capacitance provided by the guard plane. The effect of noise introduced into the PL plate or the sub array ground net will be significantly reduced.

According to one embodiment of the present invention, the guard plate is contacted to substrate ground via contacts and metal lines at the border of the PL and guard plate of local sub arrays.

According to one embodiment of the present invention, the guard plate (second electrode) is contacted to a ground mesh located in or above the substrate via contacts and metal lines at the border of the PL and the guard plate of the local sub arrays.

According to one embodiment of the present invention, each sub array has its own guard plate. As an option, the guard plate of several sub-arrays can be electrically connected to increase the capacitor and to support ground distribution over larger areas.

According to one embodiment of the present invention, the guard plate can also be used by drivers and the circuit in the periphery as a stable ground potential.

According to one embodiment of the present invention, the guard plate capacitor ensures that PL plate voltage and peripheral circuits grounded (e.g. sense amplifier) are in phase at local arrays (buffer capacitance).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of resistivity changing memory cells, each memory cell comprising a top electrode, a bottom electrode, and resistivity changing material being disposed between the top electrode and the bottom electrode,
wherein the top electrodes together form a continuous common first electrode, or wherein the continuous common first electrode which is electrically connected to all top electrodes is disposed above the top electrodes, and
wherein a second guard electrode connectable to a fixed potential is disposed above the first electrode such that the first electrode and the second guard electrode together form a capacitor.

2. The integrated circuit according to claim 1, wherein the fixed potential of the second electrode is chosen such that potential fluctuations of a potential of the first electrode are decreased during the operation of the integrated circuit.

3. The integrated circuit according to claim 1, wherein insulating material is disposed between the first electrode and the second electrode.

4. The integrated circuit according to claim 3, wherein the insulating material comprises SiO₂ or SiN or isolating carbon, hafnium based oxides or aluminum based oxides.

5. The integrated circuit according to claim 1, wherein the material of the first electrode and the second electrode comprises W, Cu, Ru, Ta, TaN, or TiN.

6. The integrated circuit according to claim 1, wherein the second electrode is electrically connected to a substrate of the integrated circuit by vias, the memory cells overlying or adjacent a surface of the substrate.

7. The integrated circuit according to claim 1, wherein the memory cells overlie or are adjacent to a surface of a substrate, wherein a fixed potential of the substrate of the integrated circuit is set to the fixed potential of the second electrode.

8. The integrated circuit according to claim 1, wherein the second electrode is patterned into a plurality of electrode subunits, each electrode subunit facing a plurality of top electrodes.

9. The integrated circuit according to claim 8, wherein the electrode subunits are electrically connected with each other.

10. The integrated circuit according to claim 8, wherein at least portions of electrode subunits are perforated or striped.

11. The integrated circuit according to claim 8, wherein each electrode subunit is electrically connected to a substrate of the integrated circuit by vias.

12. The integrated circuit according to claim 8, wherein dimensions/positions of the electrode subunits are chosen such that delaminating effects of the patterned second electrode are reduced.

13. The integrated circuit according to claim 1, wherein a distance between the first electrode and the second electrode is about 10 nm to about 30 nm.

14. The integrated circuit according to claim 1, further comprising controlling circuits or peripheral circuits coupled to the second electrode such that the fixed potential of the second electrode is supplied to the controlling circuits or peripheral circuits as a reference potential.

15. The integrated circuit according to claim 1, wherein the resistivity changing memory cells comprise phase changing memory cells.

16. The integrated circuit according to claim 1, wherein the resistivity changing memory cells comprise carbon memory cells.

17. The integrated circuit according to claim 1, wherein the resistivity changing memory cells comprise programmable metallization memory cells.

18. The integrated circuit according to claim 1, wherein the resistivity changing memory cells comprise solid electrolyte memory cells.

19. The integrated circuit according to claim 1, wherein the resistivity changing memory cells comprise magneto resistive memory cells.

20. A memory cell array comprising a plurality of resistivity changing memory cells, each memory cell comprising a top electrode, a bottom electrode, and resistivity changing material being disposed between the top electrode and the bottom electrode,
wherein the top electrodes together form a continuous common first electrode, or wherein the continuous common first electrode which is electrically connected to all top electrodes is disposed above the top electrodes, and
wherein a second electrode connectable to a fixed potential is disposed above the first electrode such that the first electrode and the second electrode together form a capacitor.

21. The memory cell array according to claim 20,
wherein the memory cell array is split into a plurality of memory cell array subunits,
wherein the second electrode is patterned into several electrode subunits,
wherein each electrode subunit faces a plurality of top electrodes, and
wherein each memory cell array subunit is at least partially covered by one of the electrode subunits.

22. A memory cell comprising a top electrode layer, a bottom electrode layer, and a resistivity changing layer disposed between the top electrode layer and the bottom electrode layer, wherein a further electrode layer electrically connected to a fixed potential is disposed adjacent the top electrode layer such that the top electrode layer and the further electrode layer together form a capacitor.

23. A method of operating an integrated circuit, wherein the integrated circuit comprises:
a plurality of resistivity changing memory cells, each memory cell comprising a top electrode, a bottom electrode, and resistivity changing material disposed between the top electrode and the bottom electrode, wherein the top electrodes together form a continuous common first electrode, or wherein the continuous common first electrode which is connected to all top electrodes is disposed above the top electrodes, and wherein a second electrode connectable to a fixed potential is disposed above the first electrode such that the first electrode and the second electrode together form a capacitor, and
a peripheral circuit or controlling circuit comprising components set to a fixed potential,
wherein the method comprises:
setting the components of the peripheral circuit or the controlling circuit to the fixed potential of the second electrode during memory cell writing and reading processes.

24. The method according to claim 23, wherein the fixed potential is used to cancel potential fluctuations occurring within signals supplied from the resistivity changing memory cells to the peripheral circuit or controlling circuit during reading processes and writing processes.

25. A method of manufacturing an integrated circuit, comprising:
providing a plurality of resistivity changing memory cells, each memory cell comprising a top electrode, a bottom electrode, and a resistivity changing layer disposed between the top electrode and the bottom electrode, wherein the top electrodes together form a continuous common first electrode layer, or wherein the continuous common first electrode layer is disposed above the top electrodes which is connected to all top electrodes,
providing an isolation layer over the first electrode layer, and
providing a second electrode layer over the isolation layer.
